(19) United States
(12) Patent Application Publication
(10) Pub. No.: US 2026/0197931 A1
(43) Pub. Date: Jul. 9, 2026

(54) ELECTRONIC DEVICE AND METAL HEAT DISSIPATION

(71) Applicant: WISTRON NEWEB CORPORATION, HSINCHU (TW)

(72) Inventors: CHIH-YANG WENG, HSINCHU (TW); Jing-Jun Lin, HSINCHU (TW); CHAO-CHIEH CHAN, HSINCHU (TW)

(21) Appl. No.: 19/185,339

(22) Filed: Apr. 22, 2025

(30) Foreign Application Priority Data
Jan. 9, 2025 (TW) 114100829

(51) Int. Cl. H05K 1/02; H05K 3/34

(52) U.S. Cl. CPC H05K 1/021; H05K 3/3494; H05K 2201/066; H05K 2201/09063; H05K 2201/09072; H05K 2201/09827; H05K 2201/09845; H05K 2201/10462; H05K 2201/10757

(57) ABSTRACT

An electronic device and a metal heat dissipation member are provided. The electronic device includes a metal heat dissipation member, a conductive member, a circuit substrate, and an electronic component. The metal heat dissipation member includes a groove. The groove includes a receiving portion and at least one through hole located around the receiving portion. The conductive member is disposed in the receiving portion. The circuit substrate is disposed above the metal heat dissipation member. The circuit substrate has an opening corresponding to the groove, and the conductive member is exposed from the opening. The electronic component is disposed above the circuit substrate and the conductive member, and the conductive member is configured to connect the electronic component and the metal heat dissipation member.

### CROSS-REFERENCE TO RELATED PATENT APPLICATION

This application claims the benefit of priority to Taiwan Patent Application No. 114100829, filed on Jan. 9, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an electronic device and its metal heat dissipation member, and more particularly to an electronic device and its metal heat dissipation member that can improve the problem of excessive bubbles and enhance heat dissipation performance.

### BACKGROUND OF THE DISCLOSURE

In the manufacturing process of conventional electronic devices, such as power amplifier devices, the substrate is first printed and populated with components, followed by transferring solder paste onto the heat-dissipating material to facilitate subsequent soldering operations. During the assembly process, the heat dissipation material is placed at the bottom, and then the substrate, solder sheet, power amplifier, and other components are stacked sequentially. After all components are assembled, reflow soldering is performed together.

However, during the reflow soldering process, bubbles are easily generated at the soldering joint between the heat dissipation material and the power amplifier, which obstructs electrical conductivity between components and affects product performance. Additionally, the overall heat dissipation effect of existing power amplifier devices still has room for improvement.

### SUMMARY OF THE DISCLOSURE

In one aspect, the present disclosure provides an electronic device, which includes a metal heat dissipation member, a conductive member, a circuit substrate, and an electronic component. The metal heat dissipation member has a groove, which includes a receiving portion and at least one through hole located around the receiving portion. The conductive member is disposed in the receiving portion. The circuit substrate is disposed above the metal heat dissipation member and has an opening corresponding to the groove, and the conductive member is exposed from the opening. The electronic component is disposed above the circuit substrate and the conductive member, and the conductive member is configured to connect the electronic component and the metal heat dissipation member.

In another aspect, the present disclosure provides a metal heat dissipation member suitable for an electronic device. The metal heat dissipation member has a groove, which includes a receiving portion and at least one through hole. The at least one through hole is located around the receiving portion.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of an electronic device of the present disclosure.

FIG. 2 is an exploded schematic diagram of the electronic device of the present disclosure.

FIG. 3 is a cross-sectional schematic diagram taken along line III-III in FIG. 1.

FIG. 4 is a top view schematic diagram of the electronic device of the present disclosure.

FIG. 5 is a schematic diagram of a metal heat dissipation member according to a first embodiment of the present disclosure.

FIG. 6 is a projection schematic diagram of a groove of the metal heat dissipation member according to the first embodiment of the present disclosure.

FIG. 7 is a bottom view schematic diagram of a metal heat dissipation member according to the second embodiment of the present disclosure.

FIG. 8 is a schematic diagram of a metal heat dissipation member according to a third embodiment of the present disclosure.

FIG. 9 is a schematic diagram of a metal heat dissipation member according to a fourth embodiment of the present disclosure.

FIG. 10 is a bottom view schematic diagram of a metal heat dissipation member according to a fifth embodiment of the present disclosure.

FIG. 11 is a cross-sectional schematic diagram taken along line XI-XI in FIG. 10.

FIG. 12 is a bottom view schematic diagram of a metal heat dissipation member according to a sixth embodiment of the present disclosure.

FIG. 13 is a cross-sectional schematic diagram taken along line XIII-XIII in FIG. 12.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

In addition, the term “or”, as used herein, should include any one or a combination of the associated enlisted items, as the case may be. The term “connect” in the context of the present disclosure means there is a physical connection between two elements and is directly or indirectly connected. The term “couple” in the context of the present disclosure means there is no physical connection between two separated elements, and the two elements are instead connected by their electric field energy where the electric field energy generated by the current of one element excites the electric field energy of the other element.

### Embodiment

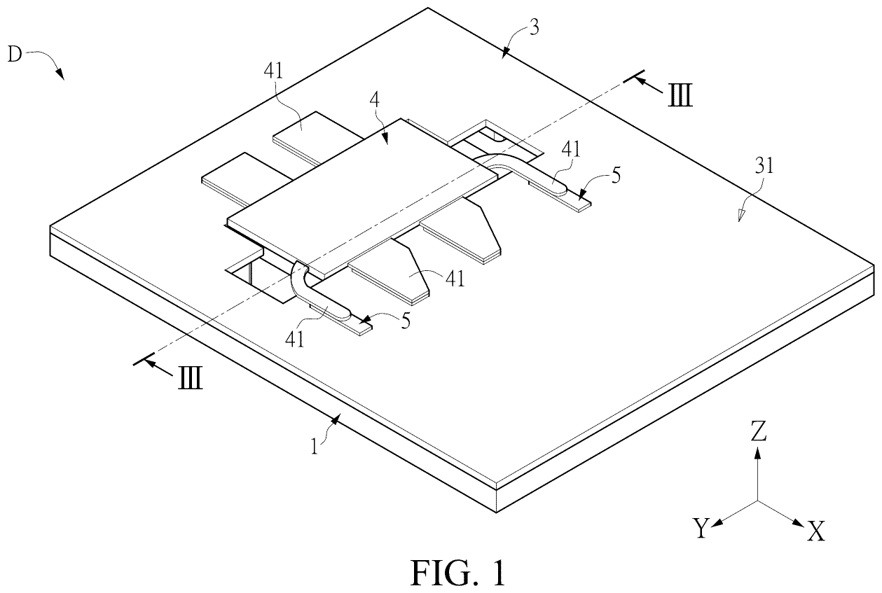

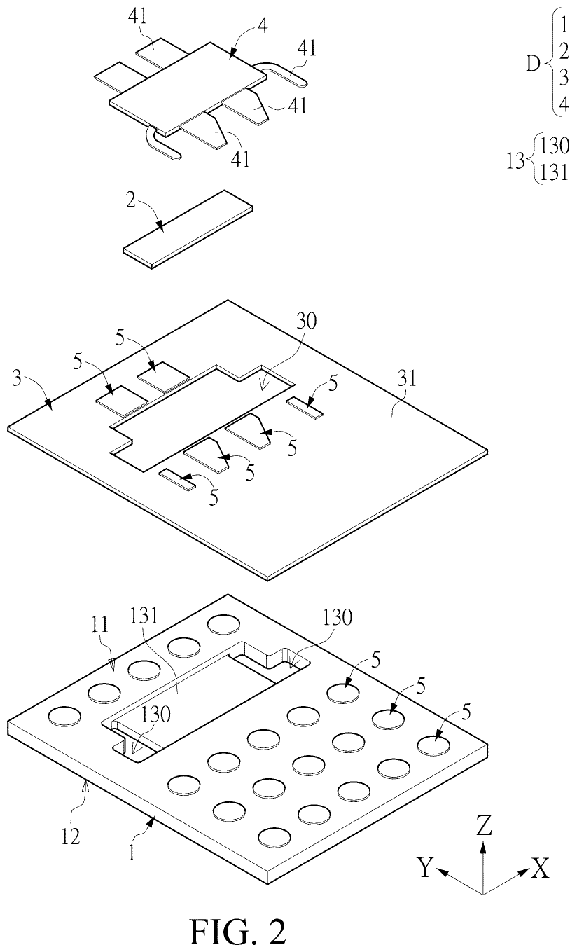

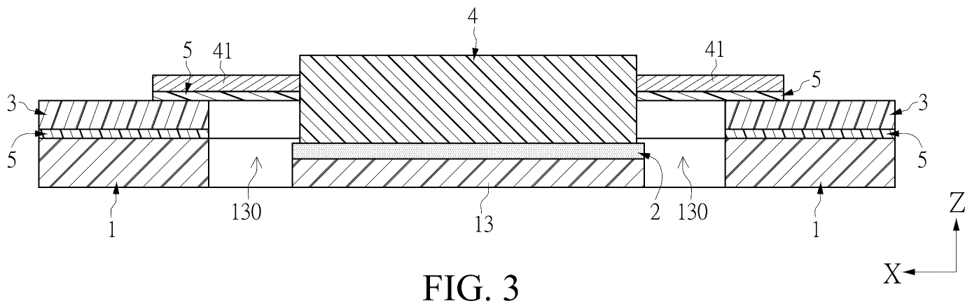

FIG. 1 is a schematic diagram of an electronic device of the present disclosure, FIG. 2 is an exploded schematic diagram of the electronic device of the present disclosure, and FIG. 3 is a cross-sectional schematic diagram taken along line III-III in FIG. 1. Referring to FIG. 1 to FIG. 3, the present disclosure provides an electronic device D, which includes: a metal heat dissipation member 1, a conductive member 2, a circuit substrate 3, and an electronic component 4. The metal heat dissipation member 1 has opposite first surface 11 and second surface 12. The metal heat dissipation member 1 has a groove 13. The groove 13 includes a receiving portion 131 and at least one through hole 130 located around the receiving portion 131. As shown in FIG. 2, there is a step difference between the receiving portion 131 in the groove 13 and the first surface 11 of the metal heat dissipation member 1. The conductive member 2 is disposed on the receiving portion 131. The circuit substrate 3 is disposed above the metal heat dissipation member 1. The circuit substrate 3 has an opening 30, and the shape of the opening 30 corresponds to the groove 13 of the metal heat dissipation member 1.

When the circuit substrate 3 is disposed above the metal heat dissipation member 1, the conductive member 2 disposed on the receiving portion 131 is exposed from the opening 30. Furthermore, the electronic component 4 is disposed above the circuit substrate 3 and the conductive member 2, and the conductive member 2 exposed in the opening 30 can connect the electronic component 4 and the metal heat dissipation member 1. For example, in the present disclosure, the electronic component 4 is a power amplifier, and the electronic device D is a power amplifier assembly composed of the power amplifier and peripheral components (such as the metal heat dissipation member 1, the conductive member 2, and the circuit substrate 3).

As shown in FIG. 2 and FIG. 3, the surface of the circuit substrate 3 is provided with multiple solder materials 5, which are respectively connected to multiple pins 41 around the electronic component 4. Additionally, the first surface 11 of the metal heat dissipation member 1 is also provided with multiple solder materials 5. During the manufacturing process of the electronic device D, the electronic component 4 is soldered to the circuit substrate 3 through the pins 41 and the solder materials 5, and the first surface 11 of the metal heat dissipation member 1 is configured to face the circuit substrate 3 and is connected to the circuit substrate 3 through the solder materials 5 provided on the first surface 11. For example, the solder materials 5 can be solder paste, copper paste, silver glue, etc., but are not limited thereto, and the shapes of the solder materials 5 are not limited.

The manufacturing of the electronic device D (such as a power amplifier assembly) can be performed using Surface Mount Technology (SMT), including at least the following steps (steps S1 to S5):
Step S1: First, printing the solder materials 5 (such as solder paste) on the circuit substrate 3;
Step S2: Placing the electronic component 4 (such as a power amplifier) at the position of the printed solder paste on the circuit substrate 3;
Step S3: Printing the solder materials 5 on the first surface 11 of the metal heat dissipation member 1;
Step S4: Placing the metal heat dissipation member 1 in a jig (not shown), and then stacking the conductive member 2, the circuit substrate 3, and the electronic component 4 sequentially to assemble the electronic device D, wherein the conductive member 2 is placed in the receiving portion 131 of the groove 13, and the pins 41 of the electronic component 4 correspond to be in contact with the solder materials 5; and
Step S5: Placing the electronic device D together with the jig in a reflow oven (not shown) for heating. During the reflow process, the conductive member 2 and the solder materials 5 will melt, connecting and fixing the electronic component 4, the circuit substrate 3, and the metal heat dissipation member 1.

The material of the metal heat dissipation member 1 can be gold or copper, but is not limited thereto. Preferably, the material of the metal heat dissipation member 1 can be made of copper, which can quickly dissipate heat, thereby improving heat dissipation efficiency, preventing the electronic component 4 (such as a power amplifier) and the circuit substrate 3 from overheating, and extending the service life of the electronic device D. Additionally, the metal heat dissipation member 1 can serve as a base plate to support the circuit substrate 3, enhancing the overall strength and rigidity of the structure, preventing warping or deformation during soldering or assembly. The metal heat dissipation member 1 can also improve the stability of the electronic component 4 during operation, reducing damage caused by vibration or improper external forces. Furthermore, the metal heat dissipation member 1 has good electrical conductivity, which can improve the signal transmission efficiency of the electronic device D, reduce signal loss, and enhance overall performance.

The conductive member 2 can be solder sheet, solder paste, copper paste, silver glue, thermal paste, or liquid metal, but is not limited thereto. The main function of the conductive member 2 is to serve as a solder to connect the electronic component 4 and the metal heat dissipation member 1, further conducting electricity and dissipating heat. The circuit substrate 3 can be a printed circuit board, but is not limited thereto, and the material of the circuit substrate 3 can be ceramic substrate, alumina substrate, aluminum nitride substrate, thin-film ceramic substrate, diamond-like carbon aluminum substrate, etc., but is not limited thereto.

It is worth mentioning that the jig provided by the present disclosure is mainly used for assembling components (i.e., the electronic component 4, the circuit substrate 3, and the metal heat dissipation member 1). It can fix the position of the components, prevent displacement, and provide the necessary pressing force during assembly to prevent warping or other improper deformation during the reflow process. Additionally, the jig can block excessive heat during the reflow process, control the temperature uniformity inside the jig, and prevent the internal electronic component 4 from being damaged due to excessive temperature.

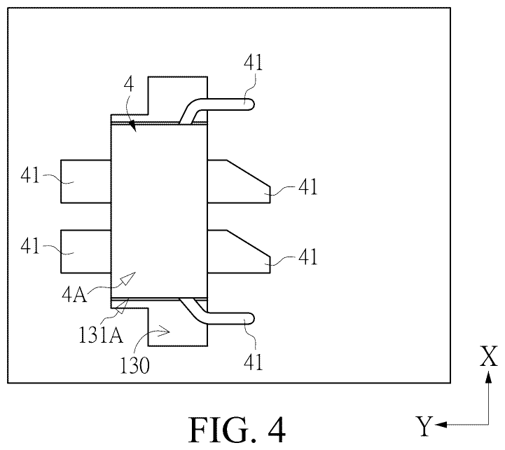

FIG. 4 is a top view schematic diagram of the electronic device of the present disclosure. Referring to FIG. 3 and FIG. 4, the area of the electronic component 4 is basically equal to or slightly smaller than the area of the receiving portion 131. As shown in FIG. 4, the first projection area 4A of the electronic component 4 projected onto the XY plane (the XY plane is parallel to the surface 31 of the circuit substrate 3) overlaps with the second projection area 131A of the receiving portion 131 projected onto the XY plane. In a preferred embodiment, the area ratio of the second projection area 131A to the first projection area 4A is between 1 and 1.5.

During the reflow stage of the manufacturing process of the electronic device D, the conductive member 2 will form molten metal at high temperatures. Since the conductive member 2 is disposed on the receiving portion 131 of the groove 13, and there is a step difference between the receiving portion 131 and the first surface 11, and because the area of the electronic component 4 is equal to or slightly smaller than the area of the receiving portion 131, the molten conductive member 2 is confined within the region of the receiving portion 131 without spreading to other areas, thereby achieving a positioning or limiting effect. As a result, the electronic component 4 can be soldered to the metal heat dissipation member 1 through the molten conductive member 2.

During the reflow process, the electronic device D is placed in a reflow oven and heated in a vacuum environment. Bubbles are generated at the soldering joint between the electronic component 4 and the metal heat dissipation member 1 and the conductive member 2, i.e., bubbles are generated in the groove 13. Currently, although reflow oven equipment is equipped with an exhaust function, bubbles generated inside convention electronic devices during soldering are still not easily released due to structural design limitations. The present disclosure forms through holes 130 within the groove 13 of the metal heat dissipation member 1, such that when the reflow oven equipment performs exhaust, airflow within the groove 13 is improved. This facilitates the release of bubbles generated during the reflow process to the external environment of the electronic device D, thereby addressing the current issue where bubbles accumulate at the soldering area, resulting in poor electrical conduction efficiency.

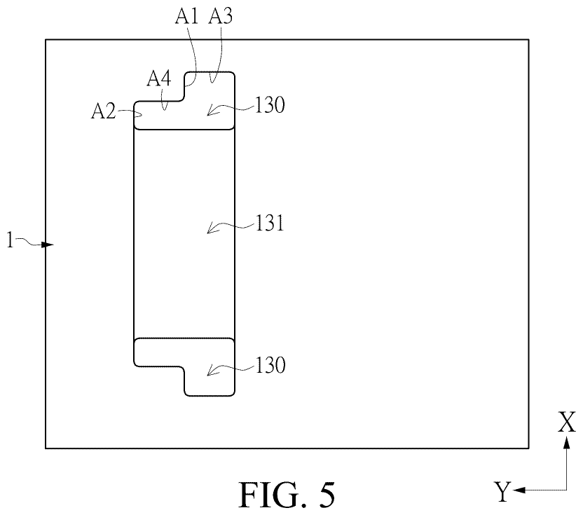

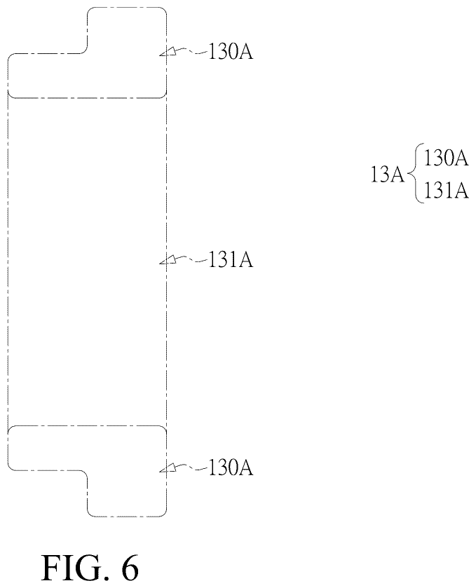

FIG. 5 is a top view schematic diagram of the metal heat dissipation member according to a first embodiment of the present disclosure, and FIG. 6 is a projection schematic diagram of the groove of the metal heat dissipation member according to the first embodiment of the present disclosure. Referring to FIG. 5 and FIG. 6, the present disclosure does not limit the number of through holes 130, as long as the through holes 130 are located in the groove 13 and adjacent to the receiving portion 131. For example, in a preferred embodiment of the present disclosure, two through holes 130 are provided in the groove 13, arranged in a mirrored symmetrical manner along a first arrangement direction (e.g., X-axis direction) on the two short sides of the receiving portion 131, and the shape of the through holes 130 is L-shaped. However, in other embodiments, the two through holes 130 can also be arranged along a second arrangement direction (e.g., Y-axis direction) on the two long sides of the receiving portion 131. The L-shaped contour design of the through holes 130 creates a pressure difference when the airflow passes through the through holes 130, thereby accelerating the flow speed of the airflow, which not only promotes bubble escape but also reduces bubble generation.

Furthermore, each through hole 130 projected onto the XY plane has a third projection area 130A, and the groove 13 projected onto the XY plane has a fourth projection area 13A. In the present disclosure, the projection areas of all through holes 130 (third projection area 130A) and the projection area of the receiving portion 131 (second projection area 131A) do not overlap. The projection area of the groove 13 (fourth projection area 13A) is equal to the sum of the projection area of the receiving portion 131 (second projection area 131A) and the projection areas of all through holes 130 (two third projection areas 130A). Preferably, the total projection area of all through holes 130 (the sum of the two third projection areas 130A in FIG. 5 and FIG. 6) accounts for at least 20% of the projection area of the groove 13 (fourth projection area 13A).

Through the structural design of the through holes 130 (i.e., the L-shaped contour of the through holes 130 and the projection area ratio of the through holes 130 to the groove 13), it is possible to increase the surface area of the through hole walls as much as possible while ensuring that the receiving portion 131 has sufficient area to carry the conductive member 2. Increasing the surface area of the through hole walls not only improves heat dissipation efficiency, further promotes bubble escape, but also affects the flow rate and pressure distribution of the fluid (i.e., the molten conductive member 2).

Furthermore, during the process of soldering the electronic component 4 to the metal heat dissipation member 1 through the molten conductive member 2, if there is excess molten conductive member 2 that spread from the receiving portion 131 to the through holes 130, the increased surface area of the through hole walls can absorb the excess solder (i.e., the excess part of the molten conductive member 2). In other words, the through holes 130 have sufficient surface area to allow the excess solder to adhere to them without further spreading to the external environment.

Continuing to refer to FIG. 2 and FIG. 5, in a preferred embodiment of the present disclosure, the surface area of all through hole walls of the through holes 130 accounts for at least 20% of the surface area of the groove walls of the groove 13. It should be noted that since the through holes 130 are located in the groove 13, the surface area of the through hole walls belongs to a part of the surface area of the groove walls of the groove 13. As shown in FIG. 5, due to the L-shaped contour of the through holes 130, each through hole 130 has a first hole wall A1 and a second hole wall A2 along the X-axis direction, which are parallel to each other but not flush. The second hole wall A2 is closer to the receiving portion 131 than the first hole wall A1, and the surface area of the first hole wall A1 is at least larger than the surface area of the second hole wall A2. Preferably, the surface area of the first hole wall A1 is at least 5% larger than the surface area of the second hole wall A2.

Additionally, each through hole 130 has a third hole wall A3 and a fourth hole wall A4 along the direction perpendicular to the second arrangement direction (Y-axis direction). The third hole wall A3 and the fourth hole wall A4 are perpendicular to the first hole wall A1 and the second hole wall A2, and the third hole wall A3 and the fourth hole wall A4 are parallel to each other but not flush. The fourth hole wall A4 is closer to the receiving portion 131 than the third hole wall A3, and the surface area of the third hole wall A3 is at least larger than the surface area of the fourth hole wall A4. Preferably, the surface area of the third hole wall A3 is at least 20% larger than the surface area of the fourth hole wall A4.

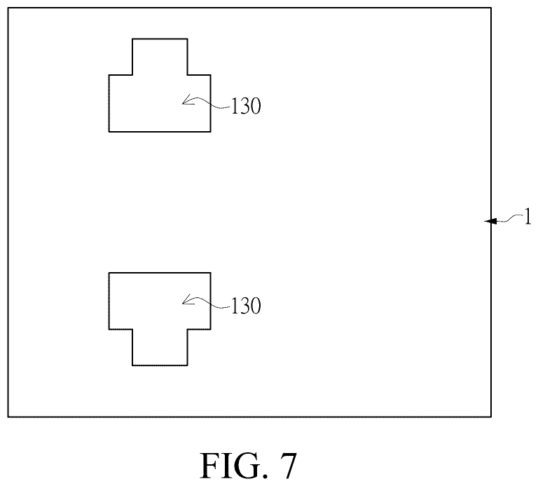

Furthermore, the present disclosure does not limit the contour shape of the through holes 130. FIG. 7 to FIG. 13 show various different embodiments of the through holes 130. It should be noted that in FIG. 7 to FIG. 13, only the through holes 130 are specifically described, while the groove 13 and the receiving portion 131 are not shown.

FIG. 7 is a schematic diagram of the metal heat dissipation member according to a second embodiment of the present disclosure. FIG. 7 shows two T-shaped through holes 130, arranged in a mirrored symmetrical manner.

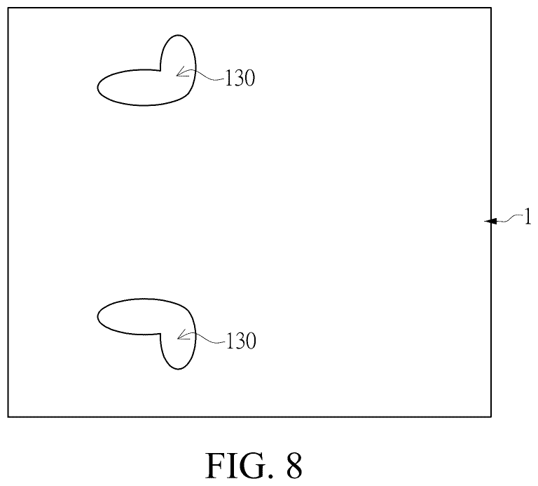

FIG. 8 is a schematic diagram of the metal heat dissipation member according to a third embodiment of the present disclosure. FIG. 8 shows two L-shaped through holes 130, arranged in a mirrored symmetrical manner, and the edges of the through holes 130 are arc-shaped, i.e., the hole walls of the through holes 130 are curved surfaces instead of flat surfaces. By designing the sides of the through holes 130 as arc-shaped, the sharp angles formed at the turns of the hole walls are reduced, allowing stress to be evenly distributed, reducing stress concentration phenomena, thereby lowering the risk of material fatigue and cracks, and improving the structural pressure resistance and fatigue resistance of the metal heat dissipation member 1.

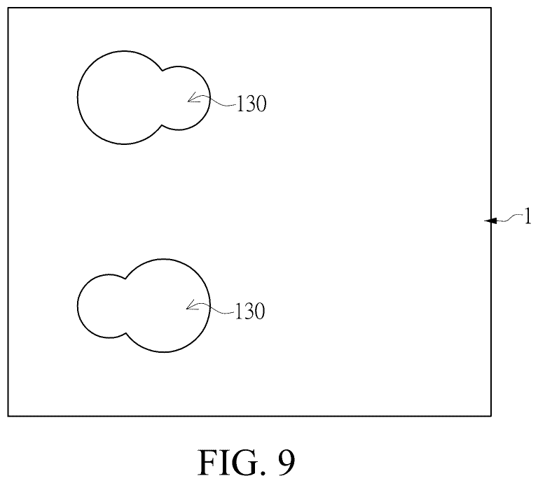

FIG. 9 is a schematic diagram of the metal heat dissipation member according to a fourth embodiment of the present disclosure. FIG. 9 shows the arrangement of two through holes 130, each of which is formed by overlapping two circular holes of different sizes into a snowman shape, arranged in a diagonal symmetrical manner. By designing the through holes 130 formed by overlapping two circular holes of different sizes, a wind speed pressure difference can be created, allowing bubbles to escape quickly.

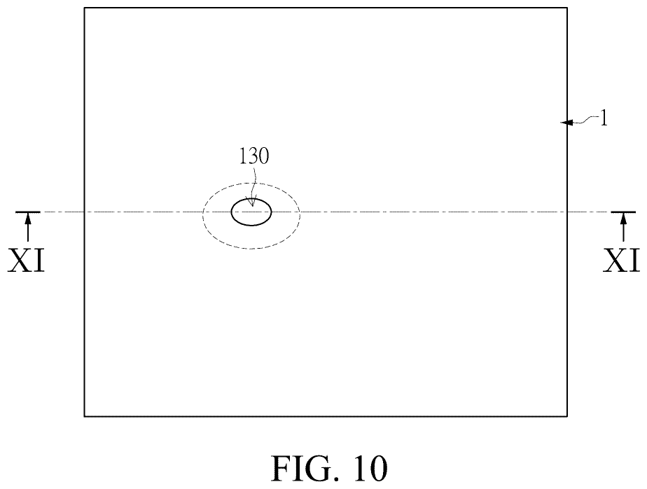

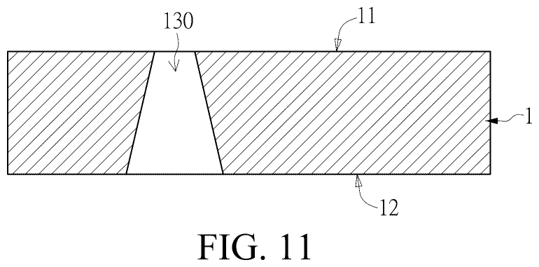

FIG. 10 is a schematic diagram of the metal heat dissipation member according to a fifth embodiment of the present disclosure, and FIG. 11 is a cross-sectional schematic diagram taken along line XI-XI in FIG. 10. Referring to FIG. 10 and FIG. 11, in the fifth embodiment, the contour of the through holes 130 is oval, with a smaller diameter on the first surface 11 of the metal heat dissipation member 1 and a larger diameter on the second surface 12. Since the first surface 11 of the metal heat dissipation member 1 is the side closer to the circuit substrate 3 when assembled with the circuit substrate 3, and the second surface 12 is the side farther from the circuit substrate 3, the diameter of the through holes 130 gradually increases from the side closer to the circuit substrate 3 toward the side farther from the circuit substrate 3.

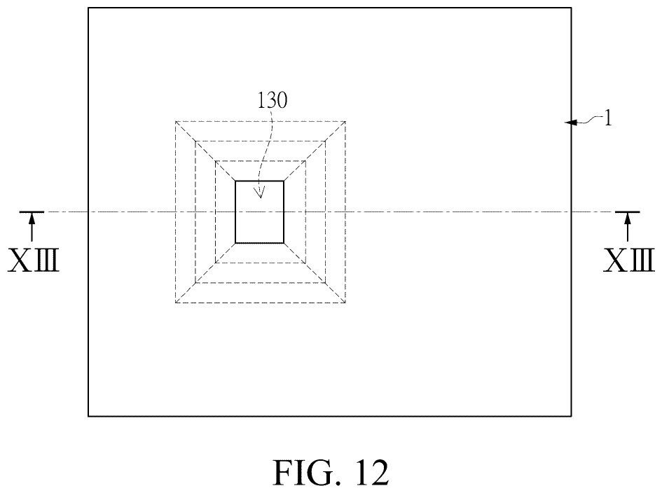

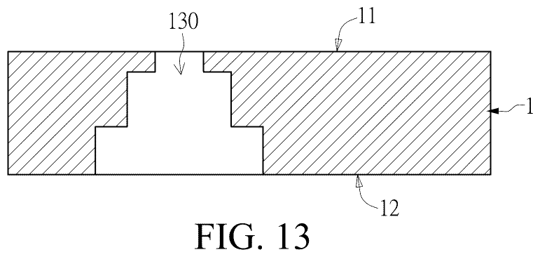

FIG. 12 is a bottom view schematic diagram of the metal heat dissipation member according to a sixth embodiment of the present disclosure, and FIG. 13 is a cross-sectional schematic diagram taken along line XIII-XIII in FIG. 12. Referring to FIG. 12 and FIG. 13, in the sixth embodiment, the contour of the through holes 130 is square. The aperture (diameter) of the through holes 130 is smaller on the first surface 11 of the metal heat dissipation member 1 and larger on the second surface 12. Since the first surface 11 of the metal heat dissipation member 1 is the side closer to the circuit substrate 3 when assembled with the circuit substrate 3, and the second surface 12 is the side farther from the circuit substrate 3, the aperture of the through holes 130 gradually increases from the side closer to the circuit substrate 3 toward the side farther from the circuit substrate 1. More precisely, the aperture of the through holes 130 gradually increases in a stepped manner from the side closer to the circuit substrate 1 toward the side farther from the circuit substrate 3.

Whether it is the fifth embodiment shown in FIG. 10 and FIG. 11 or the sixth embodiment shown in FIG. 12 and FIG. 13, the aperture or the diameter of the through holes 130 is smaller on the side closer to the circuit substrate 3 and larger on the side farther from the circuit substrate 3. By designing the gradually increasing aperture of the through holes 130, bubbles can escape more quickly. In other words, the varying aperture sizes of the through holes 130 can change the gas flow rate. Additionally, it should be noted that the gradually increasing aperture design of the through holes 130 can also be applied to the through hole types shown in the first to fourth embodiments (FIG. 5 to FIG. 9).

### Beneficial Effects of Embodiments

The electronic device D and its metal heat dissipation member 1 provided by the present disclosure have a groove 13 in the metal heat dissipation member 1. The groove 13 includes a receiving portion 131 and at least one through hole 130 located adjacent to the receiving portion 131. The groove 13 can improve the flowability of the molten metal (i.e., the conductive member 2) during soldering, restricting the molten metal to the target soldering area, and the through holes 130 near the groove 13 can promote the escape of bubbles generated during reflow soldering, further improving heat conduction.

Furthermore, the present disclosure uses the L-shaped contour design of the through holes 130 to create a pressure difference when the airflow passes through the through holes 130, thereby accelerating the flow speed of the airflow, which not only promotes bubble escape but also reduces bubble generation. Additionally, the present disclosure can utilize the shape (L-shaped contour) and size (projection area ratio of the through holes 130 to the groove 13) of the through holes 130 to increase the surface area of the through hole walls as much as possible while ensuring that the receiving portion 131 has sufficient area to carry the conductive member 2. Increasing the surface area of the through hole walls not only improves heat dissipation efficiency, promotes bubble escape, but also affects the flow rate and pressure distribution of the fluid (i.e., the molten conductive member 2).

Furthermore, during the process of soldering the electronic component 4 to the metal heat dissipation member 1 through the molten conductive member 2, if there is excess molten conductive member 2 spreading from the receiving portion 131 to the through holes 130, the increased surface area of the through hole walls can absorb the excess solder (i.e., the excess part of the molten conductive member 2). In other words, the through holes 130 have sufficient surface area to allow the excess solder to adhere to them without further spreading to the external environment.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An electronic device, comprising:
a metal heat dissipation member having a groove, the groove including a receiving portion and at least one through hole located around the receiving portion;
a conductive member disposed in the receiving portion;
a circuit substrate disposed above the metal heat dissipation member, and the circuit substrate having an opening corresponding to the groove, wherein the conductive member is exposed from the opening; and
an electronic component disposed above the circuit substrate and the conductive member, wherein the conductive member is configured to connect the electronic component and the metal heat dissipation member.

2. The electronic device according to claim 1, wherein, when the electronic component and the receiving portion are projected onto a plane to form a first projection area and a second projection area respectively, the first projection area and the second projection area overlap each other, an area ratio of the second projection area to the first projection area is between 1 to 1.5, and the plane is parallel to a surface of the circuit substrate.

3. The electronic device according to claim 1, wherein, when the at least one through hole and the groove are projected onto a plane to form a third projection area and a fourth projection area respectively, the third projection area is at least 20% of the fourth projection area, and the plane is parallel to a surface of the circuit substrate.

4. The electronic device according to claim 1, wherein a surface area of hole walls of the at least one through hole is at least 20% of a surface area of groove walls of the groove.

5. The electronic device according to claim 1, wherein a diameter of the at least one through hole gradually increases from a side closer the circuit substrate toward a side farther from the circuit substrate.

6. The electronic device according to claim 1, wherein a number of the at least one through hole are two, each of the two through holes is L-shaped, and the two through holes are arranged on two sides of the receiving portion in a mirrored symmetrical manner along an arrangement direction.

7. The electronic device according to claim 6, wherein each of the two through holes has a first hole wall and a second hole wall along the arrangement direction, the first hole wall and the second hole wall are parallel to each other but not flush, the second hole wall is closer to the receiving portion than the first hole wall, and a surface area of the first hole wall is at least larger than a surface area of the second hole wall.

8. The electronic device according to claim 7, wherein the surface area of the first hole wall is at least 5% larger than the surface area of the second hole wall.

9. The electronic device according to claim 7, wherein each of the two through holes has a third hole wall and a fourth hole wall along a direction perpendicular to the arrangement direction, the third hole wall and the fourth hole wall are perpendicular to the first hole wall and the second hole wall, the third hole wall and the fourth hole wall are parallel to each other and not flush with each other, the fourth hole wall is closer to the receiving portion than the third hole wall, and a surface area of the third hole wall is at least larger than a surface area of the fourth hole wall.

10. The electronic device according to claim 9, wherein the surface area of the third hole wall is at least 20% larger than the surface area of the fourth hole wall.

11. The electronic device according to claim 1, wherein the electronic component is configured as a power amplifier.

12. A metal heat dissipation member suitable for an electronic device, the metal heat dissipation member comprising:
a groove, the groove comprising:
a receiving portion; and
at least one through hole located around the receiving portion.

13. The metal heat dissipation member according to claim 12, wherein a surface area of hole walls of the at least one through hole is at least 20% of a surface area of groove walls of the groove.

14. The metal heat dissipation member according to claim 12, wherein the metal heat dissipation member is assembled to a circuit substrate of the electronic device, and a diameter of the at least one through hole gradually increases from a side closer to the circuit substrate toward a side farther from the circuit substrate.

15. The metal heat dissipation member according to claim 12, wherein a number of the at least one through hole are two, each of the two through holes is L-shaped, and the two through holes are arranged on two sides of the receiving portion in a mirrored symmetrical manner along an arrangement direction.

16. The metal heat dissipation member according to claim 15, wherein each of the two through holes has a first hole wall and a second hole wall along the arrangement direction, the first hole wall and the second hole wall are parallel to each other and not flush with each other, the second hole wall is closer to the receiving portion than the first hole wall, and a surface area of the first hole wall is at least larger than a surface area of the second hole wall.

17. The metal heat dissipation member according to claim 16, wherein the surface area of the first hole wall is at least 5% larger than the surface area of the second hole wall.

18. The metal heat dissipation member according to claim 16, wherein each of the two through hole has a third hole wall and a fourth hole wall along a direction perpendicular to the arrangement direction, the third hole wall and the fourth hole wall are perpendicular to the first hole wall and the second hole wall, the third hole wall and the fourth hole wall are parallel to each other and not flush with each other, the fourth hole wall is closer to the receiving portion than the third hole wall, and a surface area of the third hole wall is at least larger than a surface area of the fourth hole wall.

19. The metal heat dissipation member according to claim 18, wherein the surface area of the third hole wall is at least 20% larger than the surface area of the fourth hole wall.
